(19) United States
(12) Patent Application Publication
(10) Pub. No.: US 2016/0262264 A1
(43) Pub. Date: Sep. 8, 2016

(54) CONNECTION SUBSTRATE AND DISPLAY DEVICE HAVING THE SAME

(71) Applicant: Samsung Electronics Co., Ltd., Suwon-si (KR)

(72) Inventor: Youngbae KIM, Hwaseong-si (KR)

(21) Appl. No.: 14/983,517

(22) Filed: Dec. 29, 2015

(30) Foreign Application Priority Data
Mar. 6, 2015 (KR) 10-2015-0031664

(51) Int. Cl. H05K 1/03; H05K 1/02

(52) U.S. Cl. CPC H05K 1/0393; H05K 1/0298; H05K 2201/05; H05K 2201/10136

(57) ABSTRACT

A connection substrate and a display device including the same are provided. The connection substrate includes a first conductive portion disposed on a tensile surface of a base film and having a first thickness, a second conductive portion disposed on a compressive surface of the base film and having a second thickness smaller than the second thickness, a first insulating layer disposed on the first conductive portion and a second insulating layer disposed on the second conductive portion. A distance from a top surface of the first conductive portion to a top surface of the first insulating layer is smaller than the first thickness.

### CROSS-REFERENCE TO RELATED APPLICATIONS

This U.S. non-provisional patent application claims priority under 35 U.S.C. §119 to Korean Patent Application No. 10-2015-0031664, filed on Mar. 6, 2015, in the Korean Intellectual Property Office, the entire contents of which are hereby incorporated by reference.

### BACKGROUND OF THE INVENTION

Example embodiments of the inventive concept relate to a connection substrate and a display device, and in particular, to a connection substrate connecting a display panel to an external circuit substrate and a display device including the same.

Recently, liquid-crystal or light-emitting display devices are being widely used instead of the conventional Braun tube. The display device may include two opposite substrates and an image display layer (e.g., a liquid-crystal or light-emitting layer) provided therebetween. In addition, the display device may further include an external circuit substrate for providing signals to the image display layer and a connection substrate for connecting the external circuit substrate to the two substrates.

To realize a high-resolution display device, a flexible substrate, on which fine pitch circuits are provided, may be used for the connection substrate. However, a lifetime of the connection substrate may be reduced due to mechanical stress caused by bending the connection substrate, thus affecting the performance of the display device.

### SUMMARY

Example embodiments of the inventive concept provide a connection substrate having a higher concentration of a conductive portion in one part of the connection substrate.

Other example embodiments of the inventive concept provide a display device including the connection substrate.

According to one aspect of the inventive concept, a connection substrate may include a flexible base film having a tensile surface and a compressive surface opposite to the tensile surface, a first conductive portion disposed on the tensile surface and the first conductive portion having a first thickness, a first insulating layer disposed on the tensile surface, the first insulating layer covering the first conductive portion, a second conductive portion disposed on the compressive surface and the second conductive portion having a second thickness smaller than the first thickness, and a second insulating layer disposed on the compressive surface and the second insulating layer covering the second conductive portion. A first distance from a top surface of the first conductive portion to a top surface of the first insulating layer may be smaller than the first thickness.

In one embodiment, a second distance from a top surface of the second conductive portion to a top surface of the second insulating layer may be greater than the first distance.

In another embodiment, the first conductive portion may include a plurality of first conductive patterns spaced apart from each other in a horizontal direction substantially parallel to a side of the connection substrate, and the second conductive portion may include a plurality of second conductive patterns spaced apart from each other in the horizontal direction.

In another embodiment, each of the first conductive patterns may be disposed to be opposite a corresponding one of the second conductive patterns.

In another embodiment, each of the first and second conductive patterns may have substantially the same width, and each of the second conductive patterns may correspond to a pair of the first conductive patterns.

In another embodiment, a thickness of the first insulating layer measured from the tensile surface to a top surface of the first insulating layer may be substantially equal to a thickness of the second insulating layer measured from the compressive surface to a top surface of the second insulating layer.

According to another aspect of the inventive concept, a connection substrate may include a base film having a tensile surface and a compressive surface facing the tensile surface, an outer part including a first conductive portion disposed on the tensile surface of the base film and a first insulating layer disposed on the first conductive portion, and an inner part including a second conductive portion disposed on the compressive surface of the base film and a second insulating layer disposed on the second conductive portion. A concentration of the first conductive portion in the outer part may be greater than a concentration of the second conductive portion in the inner part

In one embodiment, the first conductive portion may have a first thickness, and the second conductive portion may have a second thickness smaller than the first thickness.

In another embodiment, a first distance measured from a top surface of the first conductive portion to a top surface of the first insulation layer may be smaller than the first thickness.

In another embodiment, the first insulation layer may be disposed on the tensile surface of the base film and cover the first conductive portion, the second insulation layer may be disposed on the compressive surface of the base film and cover the second conductive portion, and a thickness of the first insulating layer measured from the tensile surface to a top surface of the first insulating layer may be substantially the same as a thickness of the second insulating layer measured from the compressive surface to a top surface of the second insulting layer

In another embodiment, a second distance measured from a top surface of the second conductive portion and a top surface the second insulating layer may be greater than the first distance.

In another embodiment, the first conductive portion may include a plurality of first conductive patterns spaced apart from each other in a horizontal direction parallel to a side of the connection substrate, the second conductive portion may include a plurality of second conductive patterns spaced apart from each other in the horizontal direction, and a number of the first conductive patterns may be greater than that of the second conductive patterns.

In another embodiment, each of the first conductive patterns may have a first thickness, and each of the second conductive patterns may have a second thickness smaller than the first thickness.

In another embodiment, the first thickness may be greater than a first distance measured from a top surface of the first conductive portion to a top surface of the first insulation layer.

In another embodiment, each of the first and second conductive patterns may have substantially the same width, and each of the second conductive patterns may correspond to a pair of the first conductive patterns.

In another embodiment, each of the plurality of first and second conductive patterns may have substantially the same width. A plurality of paired configuration may be formed by disposing one of the second conductive patterns opposite to corresponding one of the first conductive patterns. At least one first conductive pattern may be disposed between two adjacent paired configurations.

In another embodiment, the first conductive portion may comprise a plurality of first conductive patterns spaced apart from each other in a horizontal direction parallel to a side of the connection substrate and the second conductive portion may comprise a plurality of second conductive patterns spaced apart from each other in the horizontal direction. A number of the plurality of first conductive patterns may be substantially the same as a number of the plurality of second conductive patterns.

According to still another aspect of the inventive concept, a display device may include a display panel, an external circuit substrate electrically connected to the display panel, and a connection substrate connecting the display panel with the external circuit substrate and having flexibility. The connection substrate may include a flexible base film having a tensile surface and a compressive surface opposite the tensile surface, a plurality of first conductive patterns disposed on the tensile surface, a first insulating layer disposed on the tensile surface to cover the plurality of the first conductive patterns, each of the first conductive patterns having a first thickness, a plurality of second conductive patterns disposed on the compressive surface, a second insulating layer disposed on the compressive surface to cover the plurality of the second conductive patterns, and each of the second conductive patterns having a second thickness smaller than the first thickness. A first distance from a top surface of the first conducive patterns to a top surface of the first insulating layer may be smaller than the first thickness. A concentration of the first conductive patterns over a total area of the tensile surface may be greater than a concentration of the second conductive patterns over a total area of the compressive surface.

In one embodiment, each of the first and second conductive patterns may have substantially the same width, and each of the second conductive patterns may correspond to a pair of the first conductive patterns.

In another embodiment, the first distance from a top surface of the first conducive patterns to a top surface of the first insulating layer may be smaller than a second distance measured from a top surface of the second insulating layer to a top surface of the second conducive patterns.

In another embodiment, a number of the first conductive patterns may be substantially the same as a number of the second conductive pattern or a number of the first conductive patterns is greater than a number of the second conductive pattern.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIGS. 1A and 1B are perspective views illustrating a display device.

FIG. 2 is a plan view illustrating a connection substrate of the display device of FIG. 1A.

FIGS. 3A through 3C are sectional views illustrating the connection substrate according to example embodiments of the inventive concept.

FIGS. 4A through 4C are sectional views illustrating a method of fabricating a connection substrate according to example embodiments of the inventive concept.

FIGS. 5A and 5B are sectional views respectively illustrating connection substrates according to first and second comparative examples.

FIGS. 6A and 6B are sectional views respectively illustrating connection substrates according to first and second experimental examples.

FIG. 7 is a perspective view illustrating an example of an electronic device including a display device according to example embodiments of the inventive concept.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments of the inventive concepts will now be described more fully with reference to the accompanying drawings, in which example embodiments are shown. Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

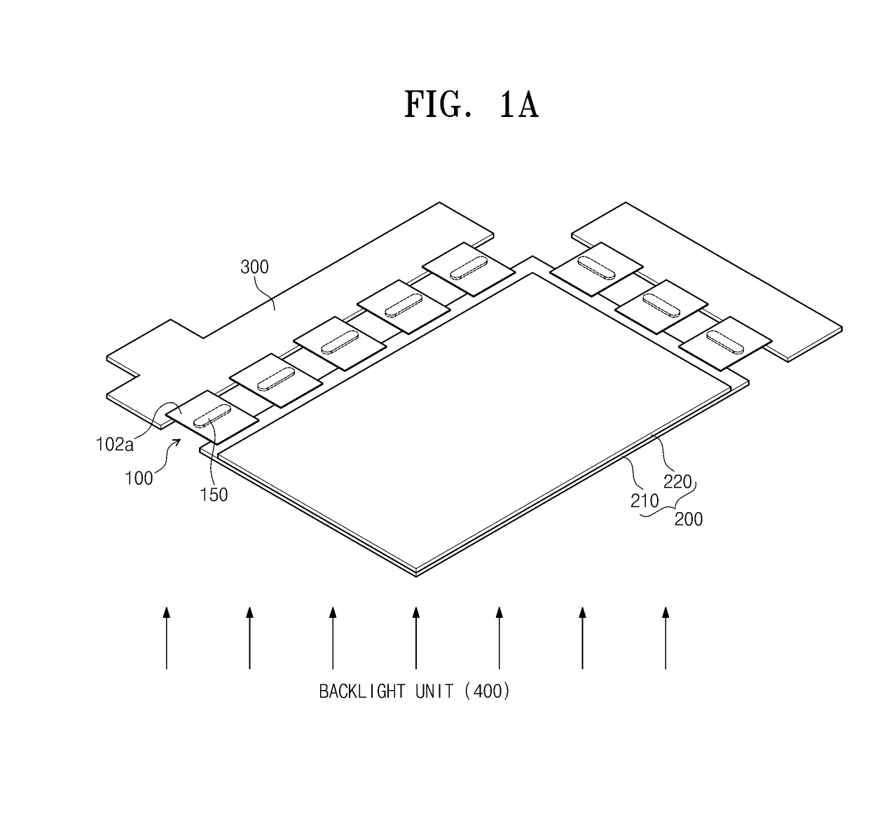

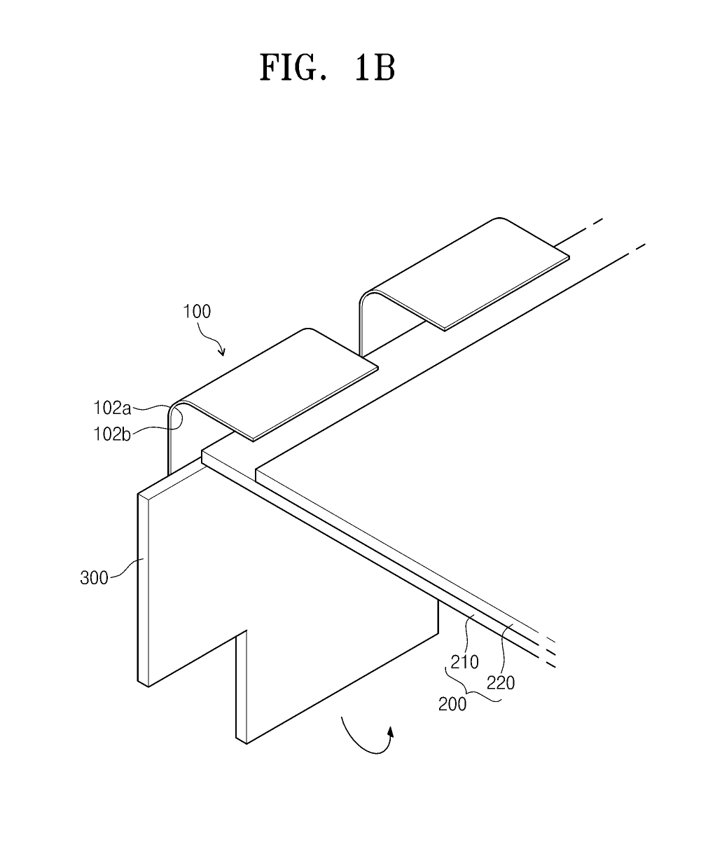

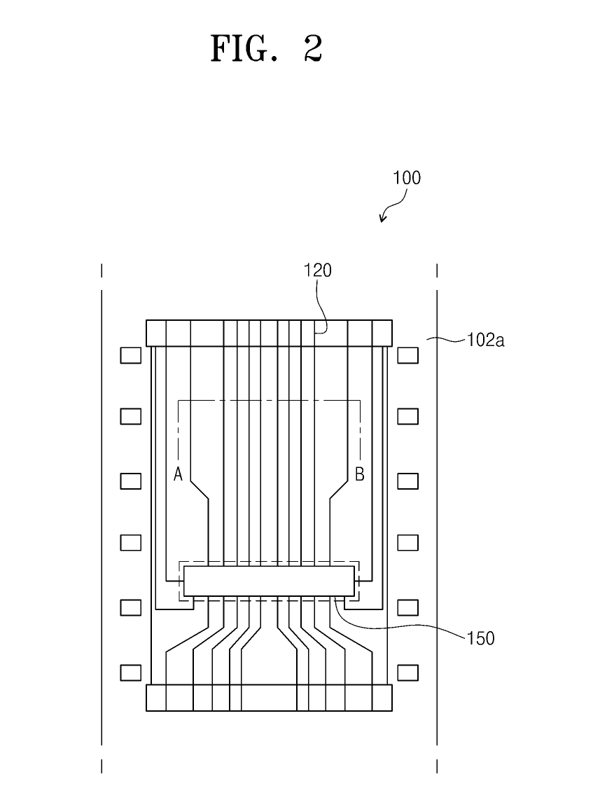

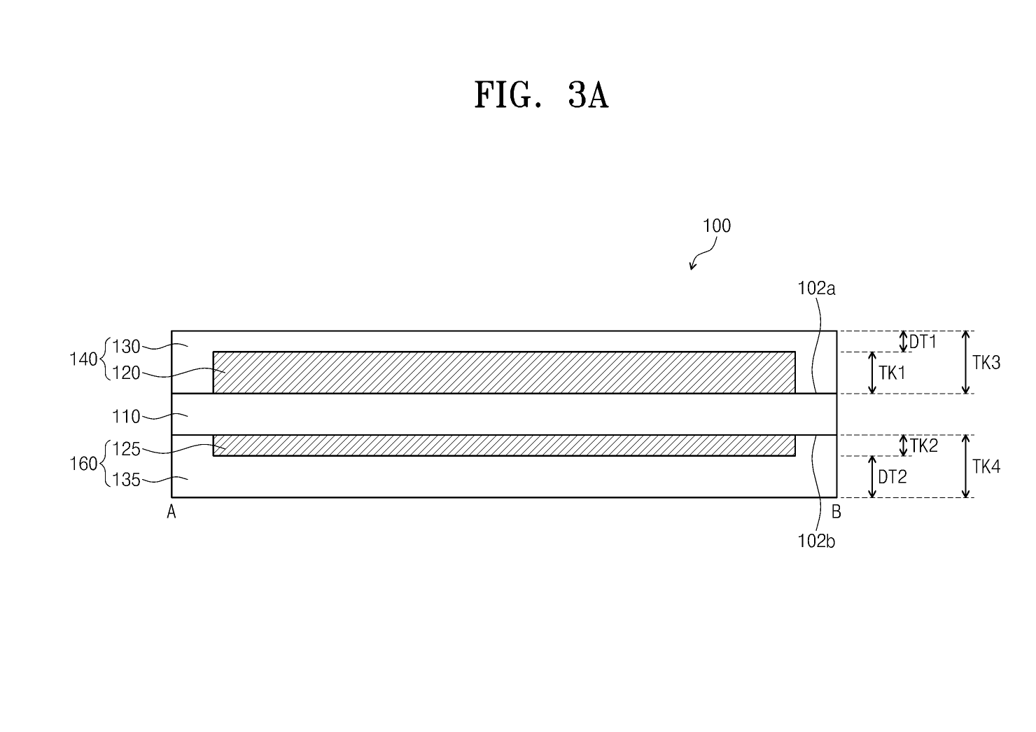

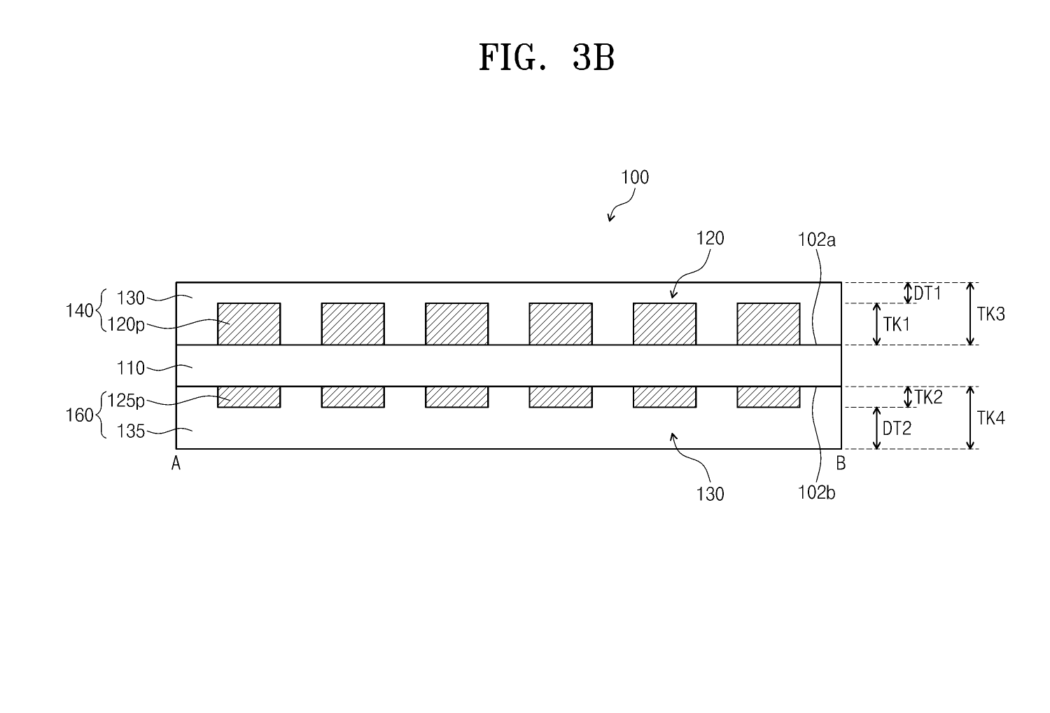

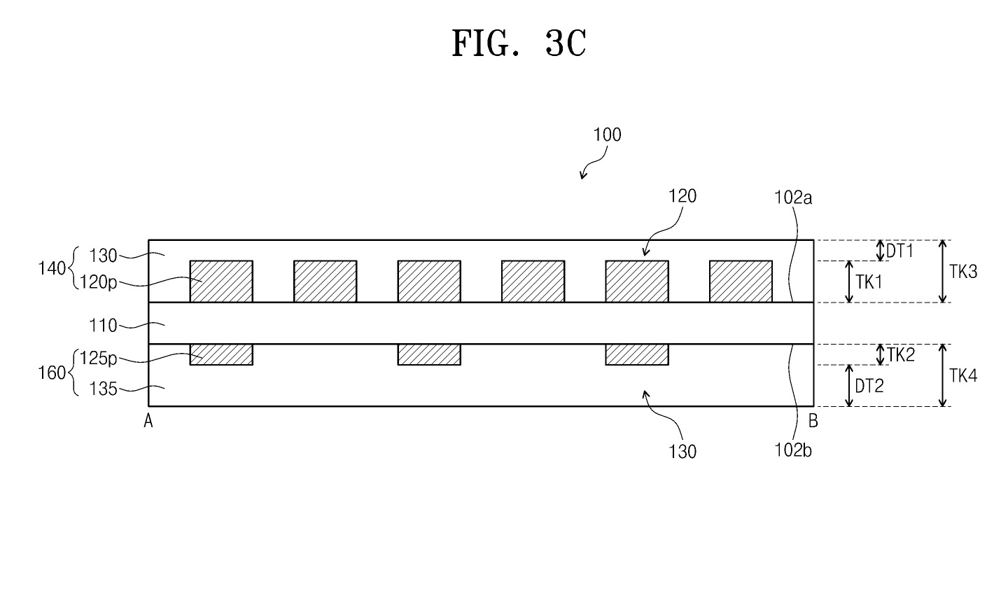

FIG. 1A is a perspective view illustrating a display device, and FIG. 1B is an enlarged perspective view illustrating a display device, in which a connection substrate is bent. FIG. 2 is a plan view illustrating the connection substrate of the display device of FIGS. 1A and 1B, and FIGS. 3A through 3C are sectional views illustrating the connection substrate according to example embodiments of the inventive concept. In detail, FIGS. 3A through 3C are sectional views taken along line A-B of FIG. 2.

The display device may be or include one of liquid crystal display (LCD), light emitting diode (LED), plasma display panel (PDP), electro luminance (EL) and electronic paper display (EPD) devices. Hereinafter, an example of the present embodiments, in which the LCD device is the display device, will be described.

Referring to FIGS. 1A, 1B, 2, and 3A, the display device may include a display panel 200, a backlight unit 400, an external circuit substrate 300, and a connection substrate 100.

The display panel 200 may include a first substrate 210 provided with first electrodes (not shown), a second substrate 220 provided with second electrodes (not shown), and a liquid crystal layer (not shown) interposed between the first and second substrates 210 and 220. The backlight unit 400 may be provided on a back or side surface of the display panel 200 and may be configured to provide light to the display panel 200.

The display device may be configured to control an electric field between the first and second electrodes and thereby allow the liquid crystal layer to make a difference in orientation, and consequently light transmittance of liquid crystal molecules (not shown) therein. Accordingly, it is possible to make a difference in transmittance of light, which is emitted from the backlight unit 400 to pass through the display panel 200 and thereby display various images to the outside.

In example embodiments, the first substrate 210 may have a larger area than that of the second substrate 220. In one embodiment, when the first substrate 210 and the second substrate 220 are attached to each other, two adjacent edge portions of the first substrate 210 may be exposed to the outside. A plurality of data pads (not shown) and a plurality of gate pads (not shown) may be provided on the exposed portions of the first substrate 210, and data lines (not shown) and gate lines (not shown) may be respectively connected to the data pads and the gate pads.

Each of the data pads and the gate pads may be electrically connected to the external circuit substrate 300 through the connection substrate 100.

The external circuit substrate 300 may include circuits (not shown) configured to process various signal information input from an external device and generate signal voltages to be used to display corresponding images. For example, the external circuit substrate 300 may be configured to have a timing controller (not shown), a power part (not shown), a gamma voltage generating part (not shown), and so forth.

Referring to FIG. 3A, the connection substrate 100 may include a base film 110, an outer part 140, and an inner part 160. The outer part 140 may include a surface exposed outside when the connection substrate 100 is bent. The outer part 140 may include a first conductive portion 120 and a first insulating layer 130. The inner part 160 may include a second conductive portion 125, and a second insulating layer 135.

The base film 110 may include at least one of polyimide, polybutylene terephthalate, polyethylene terephthalate, polysulfone, polyether, polyether imide, or polyacrylate (PAR).

The base film 110 may be configured to be flexible, thereby having a bent shape. In example embodiments, the base film 110 may include a tensile surface 102a and a compressive surface 102b facing or opposite to each other. When the base film 110 is bent, tensile stress may be exerted on the tensile surface 102a of the base film 110 and compressive stress may be exerted on the compressive surface 102b of the base film 110.

The first conductive portion 120 may be provided on the tensile surface 102a of the base film 110. In one embodiment, the first insulating layer 130 may be disposed on the tensile surface 102a of the base film 110 to cover the first conductive portion 120. The first conductive portion 120 may include at least one of metallic materials (e.g., copper (Cu), gold (Au), and aluminum (Al)). The first insulating layer 130 may include one of polyimide, epoxy and acrylic resins.

The second conductive portion 125 may be provided on the compressive surface 102b of the base film 110. In one embodiment, the second insulating layer 135 may be disposed on the compressive surface 102b of the base film 110 to cover the second conductive portion 125. The second conductive portion 125 may include at least one of metallic materials (e.g., copper (Cu), gold (Au), and aluminum (Al)). The second insulating layer 135 may include one of polyimide, epoxy and acrylic resins.

In example embodiments, a concentration of the first conductive portion 120 in the outer part 140 may be greater than a concentration of the second conductive portion 125 in the inner part 160. The concentration the first conductive portion 120 in the outer part 140 may refer to a mass or a volume of the first conductive portion 120 in the outer part 140. The concentration of the second conductive portion 125 in the inner part 160 may refer to a mass or a volume of the second conductive portion 125 in the inner part 160. In other words, the concentration of the first conductive portion 120 over a total area of the tensile surface 102a may be greater than the concentration of the second conductive portion 125 over a total area of the compressive surface 102b.

In one embodiment shown in FIG. 3A, concentrations of the first conductive portion 120 in the outer part 140 and the second conductive portions 125 in the inner part 160 may be configured to be different by adjusting thicknesses thereof. As an example, the first conductive portion 120 may have a first thickness TK1, and the second conductive portion 125 may have a second thickness TK2 smaller than the first thickness TK1.

In the example embodiments shown in FIGS. 3B and 3C, the first conductive portion 120 may include a plurality of first conductive patterns 120p that are spaced apart from each other in a horizontal direction parallel to one side of the connection substrate 100. In some embodiment, the horizontal direction is parallel to an elongated portion of a semiconductor chip 150 disposed on the connection substrate 100 (see FIG. 2 for the elongated portion). Each of the first conductive patterns 120p may have substantially the same thickness, i.e., the first thickness TK1. The second conductive portion 125 may include a plurality of second conductive patterns 125p that are spaced apart from each other in the horizontal direction. Each of the second conductive patterns 125p may have substantially the same thickness, i.e., the second thickness TK2. The second thickness TK2 may be smaller than the first thickness TK1.

In one embodiment shown in FIG. 3B, each of the first conductive patterns 120p may be disposed to be opposite to a corresponding one of the second conductive patterns 125p. The number of the first conductive patterns 120p may be equal to that of the second conductive patterns 125p. In one embodiment shown in FIG. 3C, the number of the first conductive patterns 120p may be greater than that of the second conductive patterns 125p. For example, two of the first conductive patterns 120p may correspond to each of the second conductive patterns 125p. In some embodiments, a plurality of paired configurations may be formed by disposing one of the second conductive patterns 125p opposite to corresponding one of the first conductive patterns 120p. In one embodiment, one first conductive pattern 120p may be disposed between two adjacent paired configurations along the horizontal direction. In another embodiment, there may be at least two of the first conductive patterns 120p between two adjacent paired configurations along the horizontal direction.

Referring to FIGS. 3A through 3C, the first insulating layer 130 may be formed on the tensile surface 102a of the base film 110 and may have a third thickness TK3, and the second insulating layer 135 may be formed on the compressive surface 102b of the base film 110 and may have a fourth thickness TK4. The third and fourth thicknesses TK3 and TK4 may be substantially equal to each other. In example embodiments, a first distance DT1 between top surfaces of the first conductive portion 120 and the first insulating layer 130 may be smaller than the first thickness TK1. A second distance DT2 between top surfaces of the second conductive portion 125 and the second insulating layer 135 may be greater than the first distance DT1.

Referring back to FIGS. 1A, 1B, and 2, the connection substrate 100 may further include a semiconductor chip 150 that may be mounted on the tensile surface 102a or the compressive surface 102b of the base film 110. As an example, the semiconductor chip 150 may be mounted on the tensile surface 102a of the base film 110 in a flip-chip bonding manner.

In one embodiment, the first thickness TK1 of the first conductive portion 120 may be greater than the second thickness TK2 of the second conductive portion 125. In another embodiment, the first distance DT1 between the top surfaces of the first conductive portion 120 and the top surface of the first insulating layer 130 may be smaller than the second distance DT2 between the top surfaces of the second conductive portion 125 and the top surface of the second insulating layer 135. Thus, a concentration of the first conductive portion 120 in the outer part 140 may be greater than a concentration of the second conductive portion 125 in the inner part 160. In other words, the concentration of the first conductive portion 120 over a total area of the tensile surface 102a may be greater than the concentration of the second conductive portion 125 over a total area of the compressive surface 102b. Accordingly, it is possible to reduce a stress to be exerted to the tensile surface 102a of the base film 110.

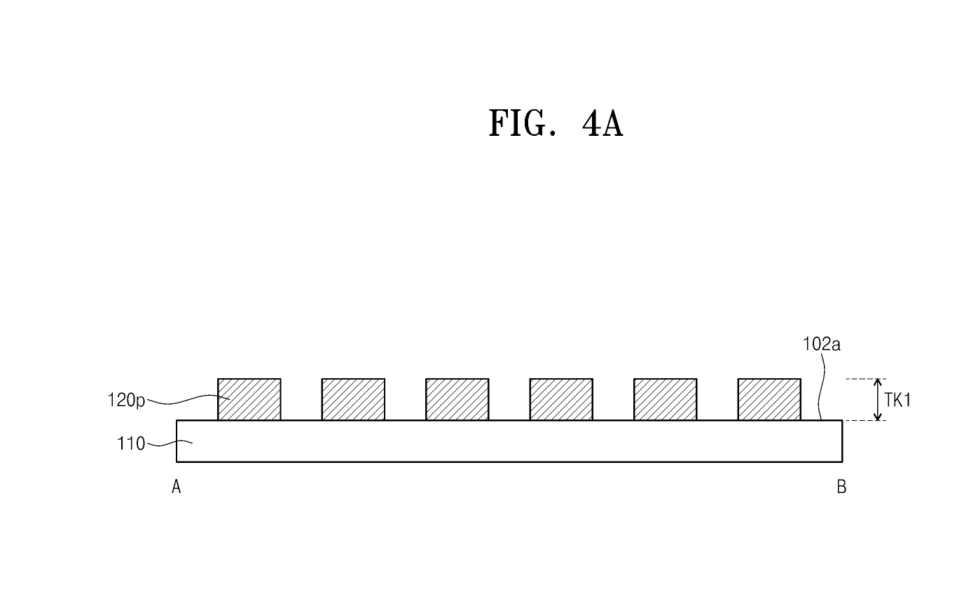

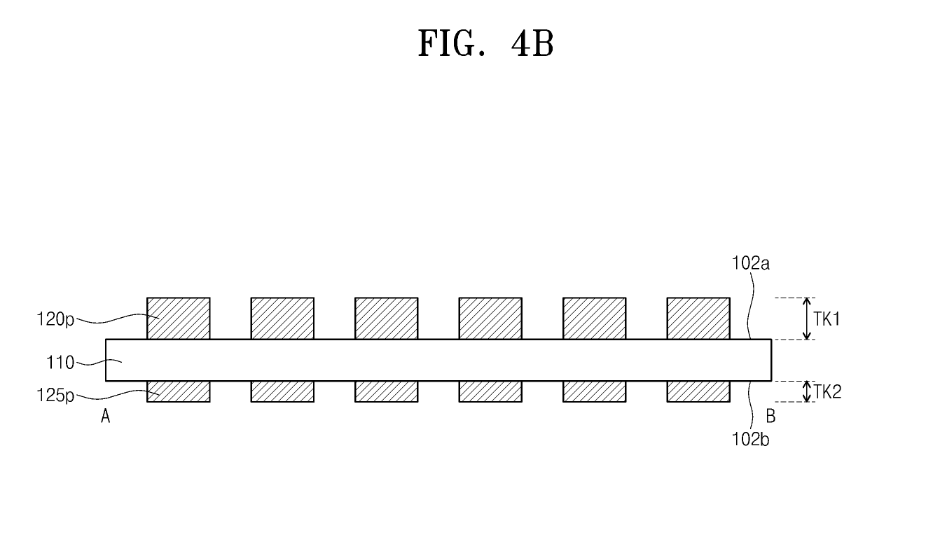

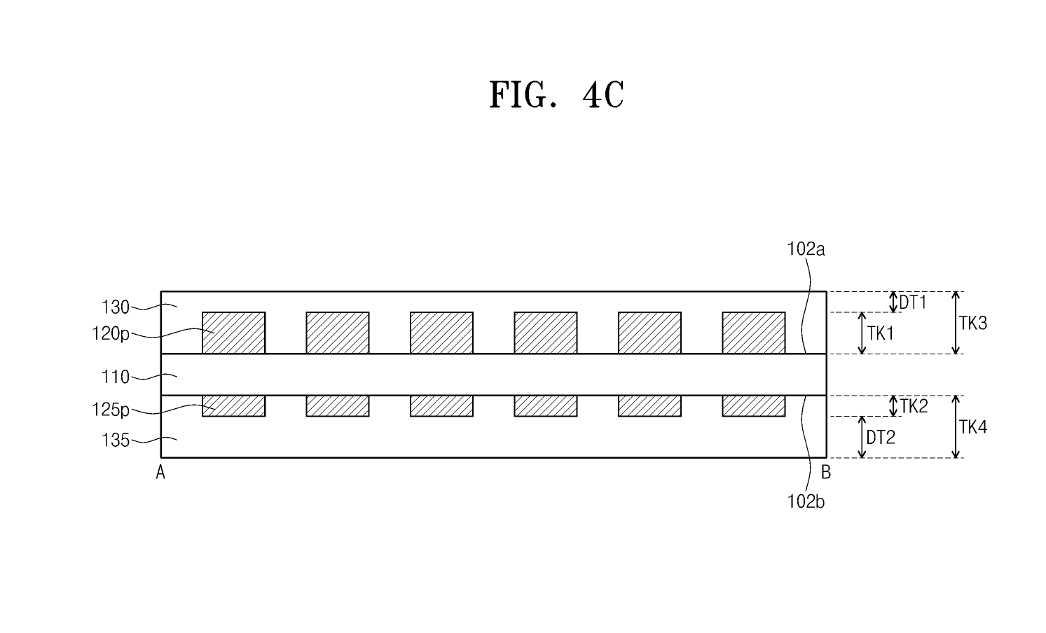

FIGS. 4A through 4C are sectional views illustrating a method of fabricating the connection substrate 100, according to example embodiments of the inventive concept.

Referring to FIG. 4A, the first conductive portion 120 including the first conductive patterns 120p may be formed on the tensile surface 102a of the base film 110.

As an example, in the case where the first conductive patterns 120p are formed to contain copper, the formation of the first conductive patterns 120p may include printing a conductive paste on the base film 110 and performing a copper-planting process.

As another example, the formation of the first conductive patterns 120p may include forming a first conductive layer (not shown) on the tensile surface 102a of the base film 110 and performing an etching process thereon.

In example embodiments, each of the first conductive patterns 120p may be formed to have the first thickness TK1. Accordingly, the first conductive portion 120 may have the first thickness TK1.

Referring to FIG. 4B, the second conductive portion 125 including the second conductive patterns 125p may be formed on the compressive surface 102b of the base film 110. The formation of the second conductive portion 125 may be substantially the same as that of the process described with reference to FIG. 4A, and thus a detailed description thereof will be omitted.

In example embodiments, each of the second conductive patterns 125p may be formed to have the second thickness TK2 smaller than the first thickness TK1. Accordingly, the second conductive portion 125 may have the second thickness TK2.

Referring to FIG. 4C, the first insulating layer 130 and the second insulating layer 135 may be formed on the tensile and compressive surfaces 102a and 102b of the base film 110, respectively, on which the first and second conductive portions 120 and 125 are formed, respectively. In example embodiments, the first and second insulating layers 130 and 135 may be formed on the base film 110 using a hydroforming press apparatus, a vacuum-type hydro press apparatus, an autoclave press apparatus, or the like.

In example embodiments, the first insulating layer 130 may be formed to have the third thickness TK3 measured between the tensile surface 102a of the base film 110 and the top surface of the first insulating layer 130, and the second insulating layer 135 may be formed to have the fourth thickness TK4 measured between the compressive surface 102b of the base film 110 and the top surface of the second insulating layer 135. The third thickness TK3 and the fourth thickness TK4 may be substantially the same. In this case, the first distance DT1 measured from the top surface of the first conductive portion 120 to the top surface of the first insulating layer 130 may be smaller than the first thickness TK1 of the first conductive portion 120. The second distance DT2 measured from the top surface of the second conductive portion 125 to the top surface of the second insulating layer 135 may be greater than the first distance DT1.

### COMPARATIVE EXAMPLE AND EXPERIMENTAL EXAMPLE

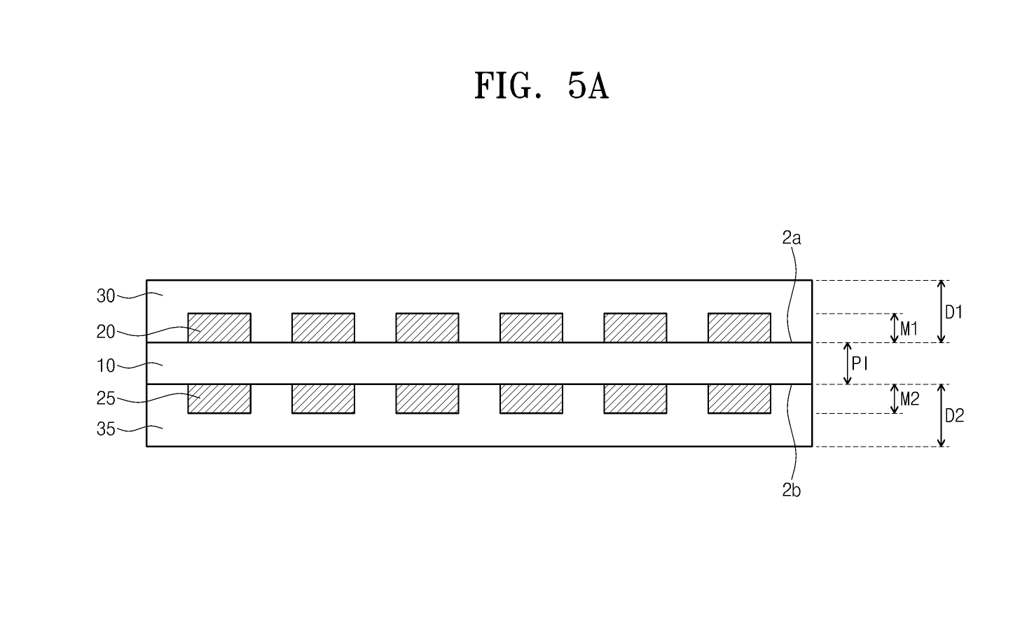

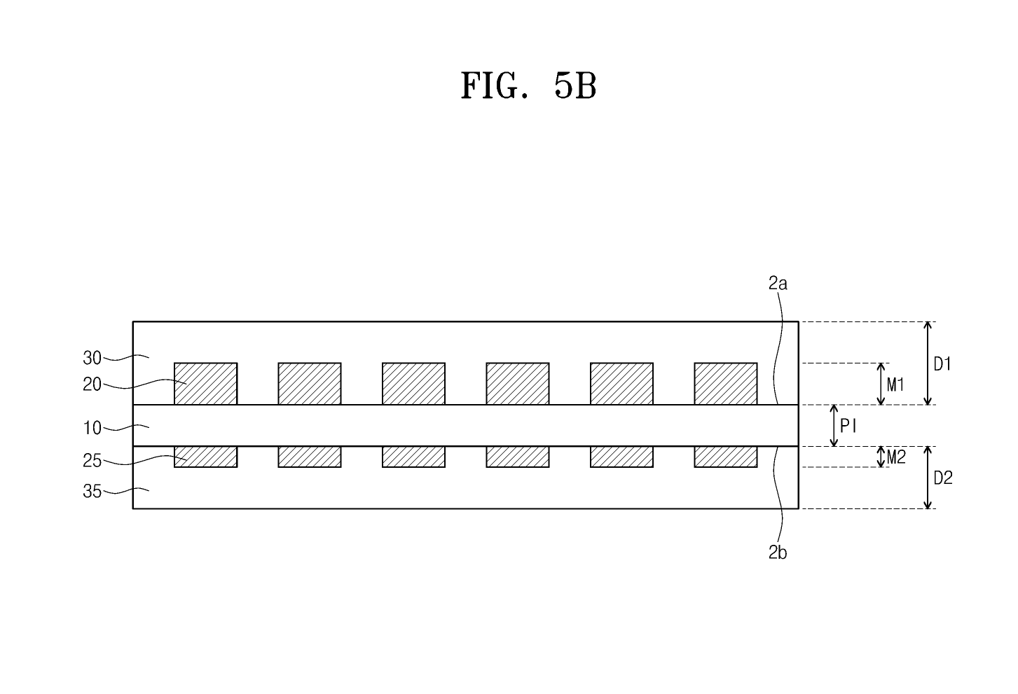

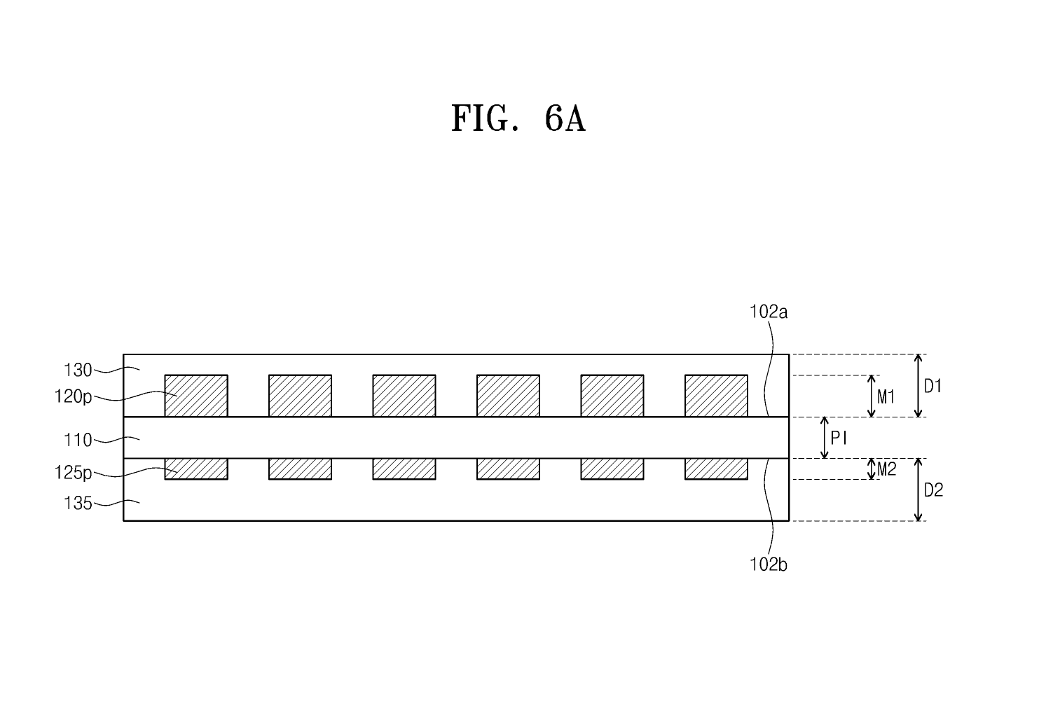

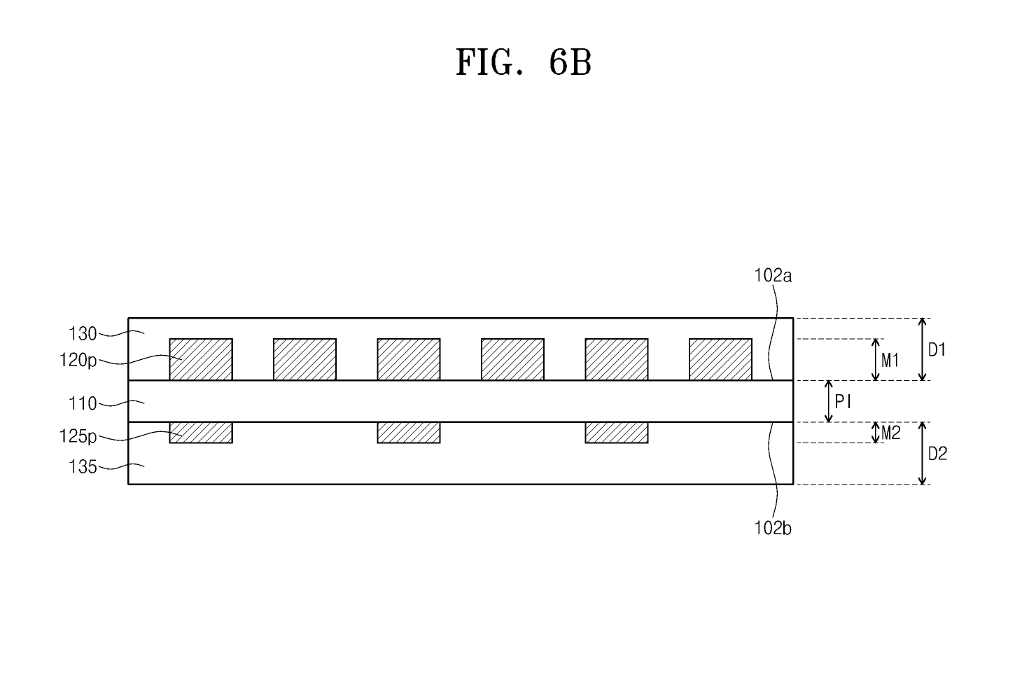

FIGS. 5A and 5B are sectional views respectively illustrating connection substrates according to first and second comparative examples. FIGS. 6A and 6B are sectional views respectively illustrating connection substrates according to first and second experimental examples.

### First Comparative Example

Referring to FIG. 5A, a base film 10 including polyimide was formed to have a thickness PI of 35 μm. On a tensile surface 2a of the base film 10, first patterns 20 including copper were formed to have a thickness M1 of 8 μm. On a compressive surface 2b of the base film 10, second patterns 25 including copper were formed to face the first patterns 20 respectively and have a thickness M2 of 8 μm. A first insulating layer 30 was formed on the first patterns 20 to have a thickness D1 of 15 μm, and a second insulating layer 35 was formed on the second patterns 25 to have a thickness D2 of 15 μm.

### Second Comparative Example

Referring to FIG. 5B, a base film 10 including polyimide was formed to have a thickness PI of 35 μm. On a tensile surface 2a of the base film 10, first patterns 20 including copper were formed to have a thickness M1 of 10 μm. On a compressive surface 2b of the base film 10, second patterns 25 including copper were formed to face the first patterns 20 respectively and have a thickness M2 of 6 μm. A first insulating layer 30 was formed on the first patterns 20 to have a thickness D1 of 20 μm, and a second insulating layer 35 was formed on the second patterns 25 to have a thickness D2 of 10 μm.

### First Experimental Example

Referring to FIG. 6A, a base film 110 including polyimide was formed to have a thickness PI of 35 μm. On a tensile surface 102a of the base film 110, first patterns 120p including copper were formed to have a thickness M1 of 10 μm. On a compressive surface 102b of the base film 110, second patterns 125p including copper were formed to face the first patterns 120p respectively and have a thickness M2 of 6 μm. A first insulating layer 130 was formed on the first patterns 120p to have a thickness D1 of 15 μm, and a second insulating layer 135 was formed on the second patterns 125p to have a thickness D2 of 15 μm.

### Second Experimental Example

Referring to FIG. 6B, a base film 110 including polyimide was formed to have a thickness PI of 35 μm. On a tensile surface 102a of the base film 110, first patterns 120p including copper were formed to have a thickness M1 of 10 μm. Second patterns 125p including copper were formed on the compressive surface 102b of the base film 110 to have a thickness M2 of 6 μm. Each of the second patterns 125p was formed to correspond to a pair of the first patterns 120p. A first insulating layer 130 was formed on the first patterns 120p to have a thickness D1 of 15 μm, and a second insulating layer 135 was formed on the second patterns 125p to have a thickness D2 of 15 μm.

Thicknesses of patterns and layers in the first and second comparative examples and the first and second experimental examples are summarized in the following table 1.

TABLE 1

| | PI | M1 | M2 | D1 | D2 | Plastic |
|---|---|---|---|---|---|---|
| | [μm] | [μm] | [μm] | [μm] | [μm] | deformation [%] |
| 1^{st} comparative | 35 | 8 | 8 | 15 | 15 | 0 |
| example | | | | | | |
| 2^{nd} comparative | 35 | 10 | 6 | 20 | 10 | 0.9 |
| example | | | | | | |
| 1^{st} experimental | 35 | 10 | 6 | 15 | 15 | −0.7 |
| example | | | | | | |
| 2^{nd} experimental | 35 | 10 | 6 | 15 | 15 | −2.1 |
| example | | | | | | |

In Table 1, PI denotes a thickness of the base film, M1 denotes a thickness of the first conductive pattern, M2 denotes a thickness of the second conductive pattern, D1 denotes a thickness of the first insulating layer, and D2 denotes a thickness of the second insulating layer.

The connection substrates according to the first and second comparative examples and the first and second experimental examples were bent, and then, plastic deformation thereof were examined. The plastic deformation of the second comparative example was increased by 0.9%, when compared with the plastic deformation of the first comparative example. In the case that both of the first conductive patterns 20 and the first insulating layer 30 had the increased thicknesses, plastic deformation was increased. The plastic deformation is associated with a lifetime of the connection substrate. For example, the more the plastic deformation, the shorter the lifetime of the connection substrate.

For the connection substrates according to the first and second experimental examples, the first conductive patterns 120p applied with a tensile stress was formed to have an increased thickness, and thus, the first insulating layer 130 was formed correspondingly to have a reduced thickness. As shown in Table 1, the plastic deformation was reduced by 0.7% and 2.1% for the first experimental example and the second experimental example, respectively. In particular, when, as in the second experimental example, the concentration of the first patterns 120p over a total area of the tensile surface was greater than the concentration of the second patterns 125p over a total area of the compressive surface, it was possible to largely reduce the plastic deformation.

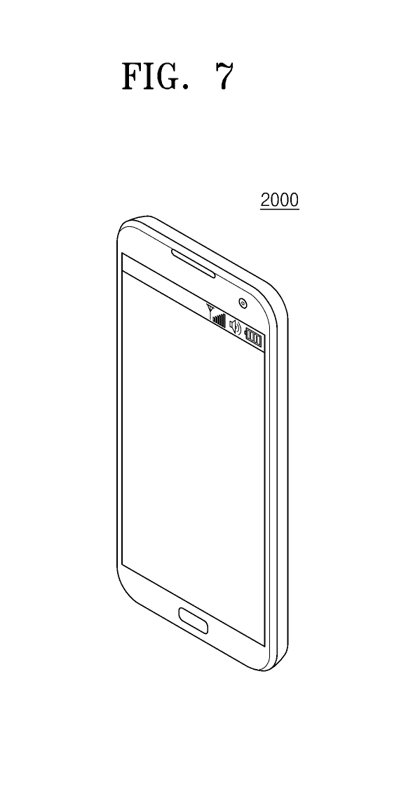

FIG. 7 is a perspective view illustrating an example of an electronic device including a display device according to example embodiments of the inventive concept.

Referring to FIG. 7, the display device according to example embodiments of the inventive concept may be applicable to mobile phones 2000. In addition, the display device may be used as a part of an electronic device, such as television sets, cameras, camcorders, personal digital assistants (PDAs), wireless phones, laptop computers, and electronic billboards.

According to example embodiments of the inventive concept, a first conductive portion, to which a tensile stress is applied, may be configured to have a concentration over a total area of the tensile surface higher than a concentration of a second conductive portion over a total area of the compressive surface, and a first insulating layer provided on the first conductive portion may be configured to have a reduced thickness measured from the top surface of the first insulating layer to the top surface of the first conductive portion. Such configuration makes it possible to reduce mechanical stress caused by the tensile stress and consequently increase a lifetime of a connection substrate.

While example embodiments of the inventive concepts have been particularly shown and described, it will be understood by one of ordinary skill in the art that variations in form and detail may be made therein without departing from the spirit and scope of the attached claims.

What is claimed is:

1. A connection substrate, comprising:
a flexible base film having a tensile surface and a compressive surface opposite to the tensile surface;
a first conductive portion disposed on the tensile surface, the first conductive portion having a first thickness;
a first insulating layer disposed on the tensile surface, the first insulation layer covering the first conductive portion;
a second conductive portion disposed on the compressive surface, the second conductive portion having a second thickness wherein the second thickness is smaller than the first thickness; and
a second insulating layer disposed on the compressive surface, the second insulating layer covering the second conductive portion,
wherein a first distance from a top surface of the first conductive portion to a top surface of the first insulating layer is smaller than the first thickness.

2. The connection substrate of claim 1, wherein a second distance from a top surface of the second conductive portion to a top surface of the second insulating layer is greater than the first distance.

3. The connection substrate of claim 1, wherein the first conductive portion comprises a plurality of first conductive patterns spaced apart from each other in a horizontal direction substantially parallel to a side of the connection substrate, and
the second conductive portion comprises a plurality of second conductive patterns spaced apart from each other in the horizontal direction.

4. The connection substrate of claim 3, wherein each of the first conductive patterns is disposed to be opposite to a corresponding one of the second conductive patterns.

5. The connection substrate of claim 3, wherein each of the first and second conductive patterns have substantially the same width, and
wherein each of the second conductive patterns corresponds to a pair of the first conductive patterns.

6. The connection substrate of claim 1, wherein a thickness of the first insulating layer measured from the tensile surface to a top surface of the first insulating layer is substantially the same as that of the second insulating layer measured from the compressive surface to a top surface of the second insulating layer.

7. A connection substrate, comprising:
a base film having a tensile surface and a compressive surface opposite the tensile surface;
an outer part including a first conductive portion disposed on the tensile surface of the base film and a first insulating layer disposed on the first conductive portion; and
an inner part including a second conductive portion disposed on the compressive surface of the base film and a second insulating layer disposed on the second conductive portion
wherein a concentration of the first conductive portion in the outer part is greater than a concentration of the second conductive portion in the inner part.

8. The connection substrate of claim 7, wherein the first conductive portion has a first thickness, and wherein the second conductive portion has a second thickness smaller than the first thickness.

9. The connection substrate of claim 8, wherein a first distance measured from a top surface of the first conductive portion to a top surface of the first insulation layer is smaller than the first thickness.

10. The connection substrate of claim 9, wherein the first insulation layer is disposed on the tensile surface of the base film and covers the first conductive portion, wherein the second insulation layer is disposed on the compressive surface of the base film and covers the second conductive portion, and wherein a thickness of the first insulating layer measured from the tensile surface to a top surface of the first insulating layer is substantially the same as a thickness of the second insulating layer measured from the compressive surface to a top surface of the second insulting layer.

11. The connection substrate of claim 10, wherein a second distance measured from a top surface of the second conductive portion to a top surface the second insulating layer is greater than the first distance.

12. The connection substrate of claim 7, wherein the first conductive portion comprises a plurality of first conductive patterns spaced apart from each other in a horizontal direction substantially parallel to a side of the connection substrate,
the second conductive portion comprises a plurality of second conductive patterns spaced apart from each other in the horizontal direction, and
a number of the plurality of first conductive patterns is greater than a number of the plurality of second conductive patterns.

13. The connection substrate of claim 12, wherein each of the first conductive patterns has a first thickness, and
each of the second conductive patterns has a second thickness smaller than the first thickness.

14. The connection substrate of claim 13, wherein the first thickness is larger than a first distance measured from a top surface of the first conductive portion to a top surface of the first insulation layer.

15. The connection substrate of claim 12, wherein each of the plurality of first and second conductive patterns have substantially the same width, and
each of the second conductive patterns corresponds to a pair of the first conductive patterns.

16. The connection substrate of claim 12, wherein each of the plurality of first and second conductive patterns have substantially the same width, and
wherein a plurality of paired configurations is formed by disposing one of the second conductive patterns opposite to a corresponding one of the first conductive patterns, and
wherein at least one first conductive pattern is disposed between two adjacent paired configurations.

17. The connection substrate of claim 7, wherein the first conductive portion comprises a plurality of first conductive patterns spaced apart from each other in a horizontal direction substantially parallel to a side of the connection substrate,
wherein the second conductive portion comprises a plurality of second conductive patterns spaced apart from each other in the horizontal direction, and
wherein a number of the plurality of first conductive patterns is substantially the same as a number of the plurality of second conductive patterns.

18. A display device, comprising:
a display panel;
an external circuit substrate electrically connected to the display panel; and
a connection substrate connecting the display panel with the external circuit substrate, the connection substrate having flexibility,
wherein the connection substrate comprises:
a flexible base film having a tensile surface and a compressive surface opposite to the tensile surface;
a plurality of first conductive patterns on the tensile surface, each of the first conductive patterns having a first thickness;
a plurality of second conductive patterns on the compressive surface, each of the second conductive patterns having a second thickness smaller than the first thickness;
a first insulating layer disposed on the tensile surface to cover the plurality of first conductive patterns, wherein a distance from a top surface of the first conducive patterns to a top surface of the first insulating layer is smaller than the first thickness; and
a second insulating layer disposed on the compressive surface to cover the plurality of the second conductive patterns,
wherein a concentration of the first conductive patterns over a total area of the tensile surface is greater than a concentration of the second conductive patterns over a total area of the compressive surface.

19. The display device of claim 14, wherein each of the first and second conductive patterns has substantially the same width, and
each of the second conductive patterns corresponds to a pair of the first conductive patterns.

20. The display device of claim 18, wherein a number of the first conductive patterns is substantially the same as a number of the second conductive patterns or a number of the first conductive patterns is greater than a number of the second conductive patterns.
